(19) United States
(12) Patent Application Publication
(10) Pub. No.: US 2019/0181018 A1
(43) Pub. Date: Jun. 13, 2019

(54) METHOD OF MANUFACTURING SEMICONDUCTOR PACKAGE BY USING BOTH SIDE PLATING

(71) Applicant: LBSEMICON CO., LTD., Gyeonggi-do (KR)

(72) Inventors: Jin Kuk LEE, Gyeonggi-do (KR); Sang Hoon AN, Gyeonggi-do (KR)

(21) Appl. No.: 16/211,962

(22) Filed: Dec. 6, 2018

(30) Foreign Application Priority Data
Dec. 13, 2017 (KR) 10-2017-0171152

(51) Int. Cl. H01L 21/56; H01L 23/00; H01L 23/31; H01L 23/522

(52) U.S. Cl. CPC H01L 21/56; H01L 24/11; H01L 24/17; H01L 2924/01029; H01L 23/5226; H01L 2224/0401; H01L 2924/01022; H01L 23/3171

(57) ABSTRACT

Provided is a method of manufacturing a semiconductor package, the method including providing an insulating substrate having a conductive via pattern, forming a first anti-scratch protection layer on a bottom surface of the insulating substrate, forming a first plated pattern and a first passivation pattern on a top surface of the insulating substrate, removing the first anti-scratch protection layer, forming a second anti-scratch protection layer on the top surface of the insulating substrate to cover the first plated pattern and the first passivation pattern, forming a second plated pattern and a second passivation pattern on the bottom surface of the insulating substrate, and removing the second anti-scratch protection layer.

### CROSS-REFERENCE TO RELATED PATENT APPLICATION

This application claims the benefit of Korean Patent Application No. 10-2017-0171152, filed on Dec. 13, 2017, in the Korean Intellectual Property Office, the disclosure of which is incorporated herein in its entirety by reference.

### BACKGROUND

### 1. Field

The present invention relates to a method of manufacturing a semiconductor package and, more particularly, to a method of manufacturing a semiconductor package by using both surfaces of a substrate.

### 2. Description of the Related Art

Currently, the goal of the electronic industry is to manufacture light, compact, high-speed, multi-functional, high-performance, and high-reliability products at low costs. One of main technologies capable of enabling setup of such a goal in product designing is packaging technology.

A related art includes Korean Application Publication 10-2007-0077686 published on Jul. 27, 2007 and entitled “Wafer Level Chip Scale Package (WLCSP) comprising bumppad of NSMD type and manufacturing method thereof”.

### SUMMARY

The present invention provides a method of manufacturing a semiconductor package by using both surfaces of a substrate, the method being capable of preventing scratches. However, the scope of the present invention is not limited thereto.

According to an aspect of the present invention, there is provided a method of manufacturing a semiconductor package, the method including providing an insulating substrate having a conductive via pattern, forming a first anti-scratch protection layer on a bottom surface of the insulating substrate, forming a first plated pattern and a first passivation pattern on a top surface of the insulating substrate, removing the first anti-scratch protection layer, forming a second anti-scratch protection layer on the top surface of the insulating substrate to cover the first plated pattern and the first passivation pattern, forming a second plated pattern and a second passivation pattern on the bottom surface of the insulating substrate, and removing the second anti-scratch protection layer.

The insulating substrate may include a glass substrate or a silicon substrate.

The plated pattern may include a single or stacked plated pattern including at least one selected from among copper (Cu), nickel (Ni), and gold (Au).

The method may further include forming an under bump metal (UBM) pattern between the conductive via pattern and the plated pattern.

The plated pattern may include a single or stacked plated pattern including at least one selected from among Cu, Ni, and Au, and the UBM pattern may include a titanium (Ti) layer, and a Cu layer on the Ti layer, or includes a titanium tungsten (TiW) layer, and a Cu layer on the TiW layer.

The anti-scratch protection layer may include a deposited TiW layer or a deposited Ti layer.

The anti-scratch protection layer may be a detachable insulating tape layer and may include an ultra-violet (UV) tape layer that is detachable by irradiating UV light thereon.

The anti-scratch protection layer may prevent warpage of the insulating substrate in a process of forming the plated pattern or the passivation pattern on the top and bottom surfaces of the insulating substrate.

### BRIEF DESCRIPTION OF THE DRAWINGS

The above and other features and advantages of the present invention will become more apparent by describing in detail embodiments thereof with reference to the attached drawings in which:

FIG. 1 is a cross-sectional view of a semiconductor package according to an embodiment of the present invention;

FIG. 2 is a flowchart of a method of manufacturing a semiconductor package, according to an embodiment of the present invention;

FIGS. 3A to 3O are sequential cross-sectional views for describing the method of manufacturing a semiconductor package, according to an embodiment of the present invention;

FIG. 4 is a flowchart of a method of manufacturing a semiconductor package, according to a comparative example of the present invention;

FIGS. 5A to 5L are sequential cross-sectional views for describing the method of manufacturing a semiconductor package, according to a comparative example of the present invention;

FIG. 6 is a table showing scratches occurring in the method of manufacturing a semiconductor package, according to a comparative example of the present invention;

FIG. 7 is a cross-sectional view showing that overplating occurs in the method of manufacturing a semiconductor package, according to a comparative example of the present invention;

FIG. 8A includes microscope images showing whether residues remain after an ultra-violet (UV) tape layer is detached under various conditions when the UV tape layer is used as an anti-scratch protection layer in the method of manufacturing a semiconductor package, according to an embodiment of the present invention; and

FIG. 8B includes microscope images showing whether residues remain after a foam tape layer is detached under various conditions when the foam tape layer is used as an anti-scratch protection layer in the method of manufacturing a semiconductor package, according to an embodiment of the present invention.

### DETAILED DESCRIPTION

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the sizes of elements may be exaggerated or reduced for convenience of explanation.

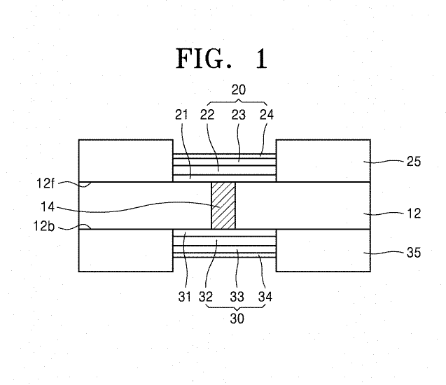

FIG. 1 is a cross-sectional view of a semiconductor package according to an embodiment of the present invention.

Referring to FIG. 1, the semiconductor package according to an embodiment of the present invention includes an insulating substrate 12 having a conductive via pattern 14, a first plated pattern 20 and a first passivation pattern 25 on a top surface 12f of the insulating substrate 12, and a second plated pattern 30 and a second passivation pattern 35 on a bottom surface 12b of the insulating substrate 12. The semiconductor package further includes a first under bump metal (UBM) pattern 21 between the insulating substrate 12 and the first plated pattern 20, and a second UBM pattern 31 between the insulating substrate 12 and the second plated pattern 30.

The insulating substrate 12 may include, for example, a glass substrate or a silicon substrate. Alternatively, the insulating substrate 12 may include a substrate including another insulating material.

The conductive via pattern 14 may include a copper (Cu) pattern. The first plated pattern 20 may include a single or stacked plated pattern including at least one selected from among Cu, nickel (Ni), and gold (Au). For example, the first plated pattern 20 may include a pattern in which a Cu pattern 22, a Ni pattern 23, and an Au pattern 24 are sequentially stacked on one another. Alternatively, the first plated pattern 20 may include only a single Cu pattern, only a single Ni pattern, or only a single Au pattern. Otherwise, the first plated pattern 20 may include a pattern including a conductive material(s) other than Cu, Ni, and Au.

The second plated pattern 30 may include a single or stacked plated pattern including at least one selected from among Cu, Ni, and Au. For example, the second plated pattern 30 may include a pattern in which a Cu pattern 32, a Ni pattern 33, and an Au pattern 34 are sequentially stacked on one another. Alternatively, the second plated pattern 30 may include only a single Cu pattern, only a single Ni pattern, or only a single Au pattern. Otherwise, the second plated pattern 30 may include a pattern including a conductive material(s) other than Cu, Ni, and Au.

Each of the first and second UBM patterns 21 and 31 may include a titanium (Ti) layer, and a Cu layer on the Ti layer, or include a titanium tungsten (TiW) layer, and a Cu layer on the TiW layer.

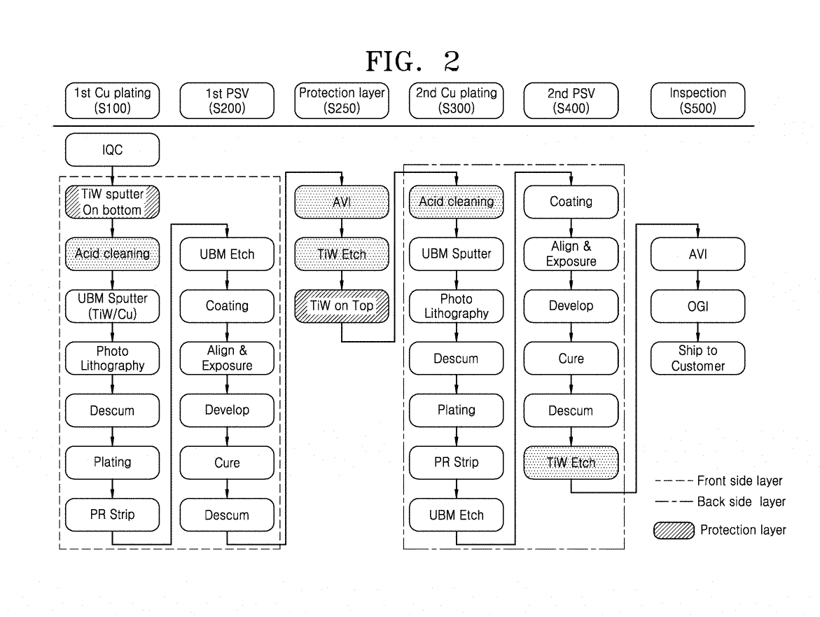

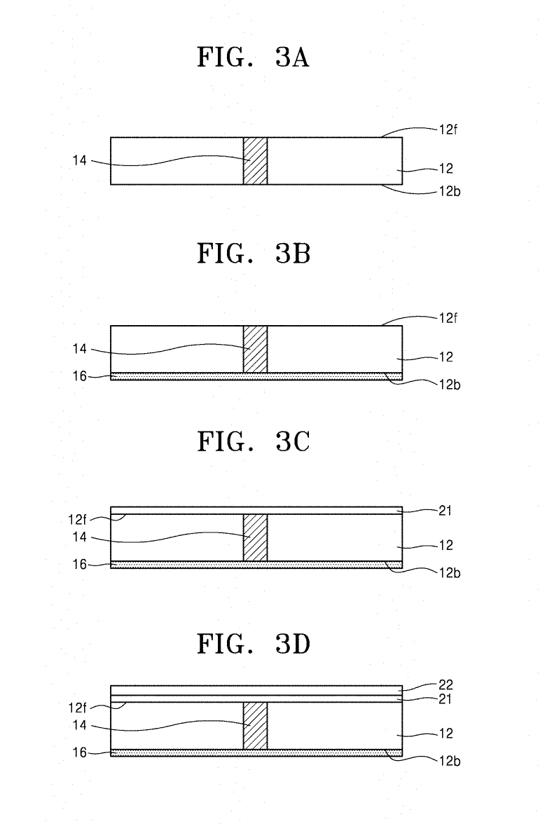

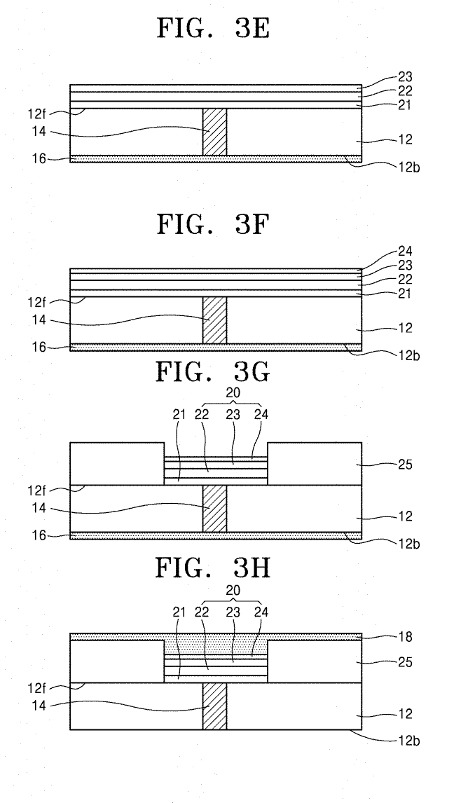

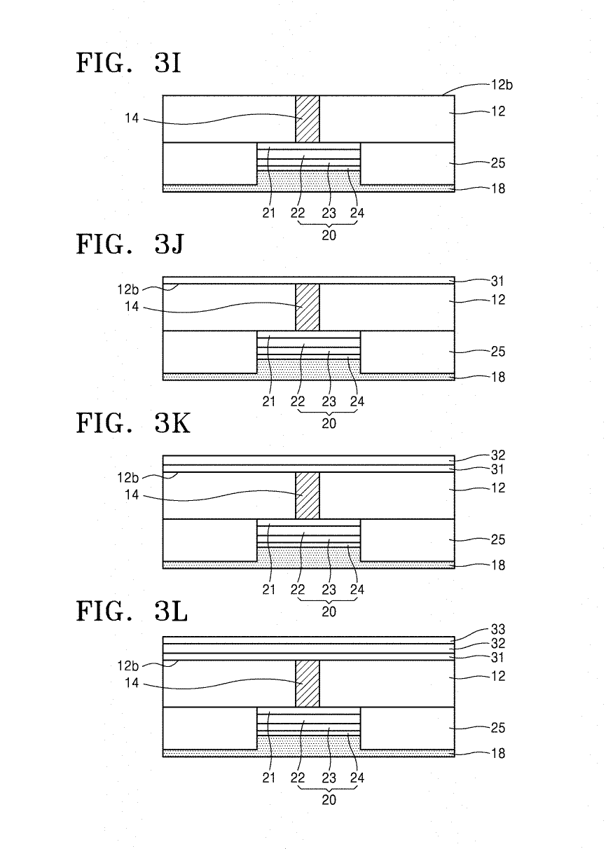

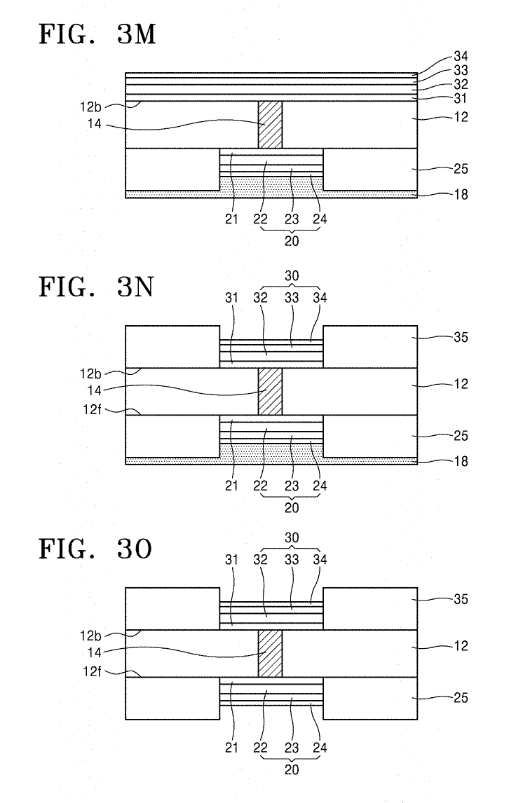

FIG. 2 is a flowchart of a method of manufacturing a semiconductor package, according to an embodiment of the present invention, and FIGS. 3A to 3O are sequential cross-sectional views for describing the method of manufacturing a semiconductor package, according to an embodiment of the present invention.

Referring to FIGS. 2 and 3A to 3O, the method of manufacturing a semiconductor package, according to an embodiment of the present invention, sequentially includes operation S100 for forming the first plated pattern 20 including a Cu plated layer, on the top surface 12f of the insulating substrate 12 having the conductive via pattern 14, operation S200 for forming the first passivation pattern 25 on the top surface 12f of the insulating substrate 12 having the conductive via pattern 14, operation S250 for removing or forming an anti-scratch protection layer from or on the bottom surface 12b and the top surface 12f of the insulating substrate 12, operation S300 for forming the second plated pattern 30 on the bottom surface 12b of the insulating substrate 12, operation S400 for forming the second passivation pattern 35 on the bottom surface 12b of the insulating substrate 12, and operation S500 for performing inspection to detect a defect.

Operation S100 for forming the first plated pattern 20 including the Cu plated layer, on the top surface 12f of the insulating substrate 12 having the conductive via pattern 14 will now be described in detail.

Referring to FIG. 3A, incoming quality control (IQC) is performed on the insulating substrate 12 having the conductive via pattern 14. The conductive via pattern 14 may include a Cu pattern, and the insulating substrate 12 may include a glass substrate or a silicon substrate. Alternatively, the insulating substrate 12 may include a substrate including another insulating material.

Referring to FIG. 3B, a first anti-scratch protection layer 16 is formed on the bottom surface 12b of the insulating substrate 12. The first anti-scratch protection layer 16 may include a deposited TiW layer. The deposited TiW layer may be formed based on, for example, a sputtering process. Alternatively, the first anti-scratch protection layer 16 may include a deposited Ti layer or an insulating tape layer.

Referring to FIG. 3C, acid cleaning is performed and then the first UBM pattern 21 is formed on the top surface 12f of the insulating substrate 12. The first UBM pattern 21 may include a TiW layer, and a Cu layer on the TiW layer.

Referring to FIGS. 3D to 3F, the Cu pattern 22, the Ni pattern 23, and the Au pattern 24 may be sequentially formed on the first UBM pattern 21 based on a plating process. For the plating process, a plating region may be defined by coating a photoresist layer and pattering the photoresist layer based on a lithography process. A descum process may be performed to obtain the photoresist pattern in an accurate shape. After the plating process is performed, the photoresist pattern is removed.

Operation S200 for forming the first passivation pattern 25 on the top surface 12f of the insulating substrate 12 having the conductive via pattern 14 will now be described in detail.

Referring to FIG. 3G, the first UBM pattern 21 is etched into a certain pattern. The first plated pattern 20 may also be etched into the certain pattern. Subsequently, to form the first passivation pattern 25, a polybenzoxazole (PBO) layer may be coated as a first passivation layer. PBO is a material of the first passivation layer. The material of the first passivation layer may be replaced with polyimide (PI), benzocyclobutene (BCB), bismaleimide triazine (BT), phenolic resin, epoxy, silicone, silicon oxide (SiO₂), silicon nitride (Si₃N₄), or an equivalent thereof.

Subsequently, the first passivation layer is selectively exposed using a mask, and then a development process for selectively removing the first passivation layer is performed by supplying a developer. The first passivation pattern 25 obtained due to the development process is heated and cured. Additionally, a descum process may be performed on the first passivation pattern 25.

Operation S250 for removing or forming the anti-scratch protection layer from or on the bottom surface 12b and the top surface 12f of the insulating substrate 12 will now be describe in detail.

Operations S100 and S200 described above are applied to the top surface 12f of the insulating substrate 12, and the bottom surface 12b of the insulating substrate 12 is mounted in direct contact with an apparatus during operations S100 and S200. In this process, scratches may occur on the bottom surface 12b of the insulating substrate 12. According to the present invention, since the first anti-scratch protection layer 16 is formed on the bottom surface 12b of the insulating substrate 12 before a material layer is formed and etched on the top surface 12f of the insulating substrate 12, scratches on the bottom surface 12b may be fundamentally prevented.

Subsequently, to form the second plated pattern 30 and the second passivation pattern 35 on the bottom surface 12b of the insulating substrate 12, the first anti-scratch protection layer 16 formed on the bottom surface 12b is removed. Since the first plated pattern 20 and the first passivation pattern 25 formed on the top surface 12f of the insulating substrate 12 are mounted in direct contact with the apparatus while the second plated pattern 30 and the second passivation pattern 35 are being formed on the bottom surface 12b of the insulating substrate 12, scratches may occur on the first plated pattern 20 and the first passivation pattern 25. To prevent scratches, a second anti-scratch protection layer 18 may be formed on the first plated pattern 20 and the first passivation pattern 25. The second anti-scratch protection layer 18 may include a deposited TiW layer. The deposited TiW layer may be formed based on, for example, a sputtering process. Alternatively, the second anti-scratch protection layer 18 may include a deposited Ti layer or an insulating tape layer.

In particular, the insulating tape layer as an anti-scratch protection layer may include an ultra-violet (UV) tape layer. The UV tape layer is an insulating tape layer that is detachable by irradiating UV light thereon. Although a foam tape layer is also usable as the insulating tape layer, since no residues are required after the insulating tape layer serving as an anti-scratch protection layer is detached, the UV tape layer is more preferable than the foam tape layer. Test results thereof will now be described.

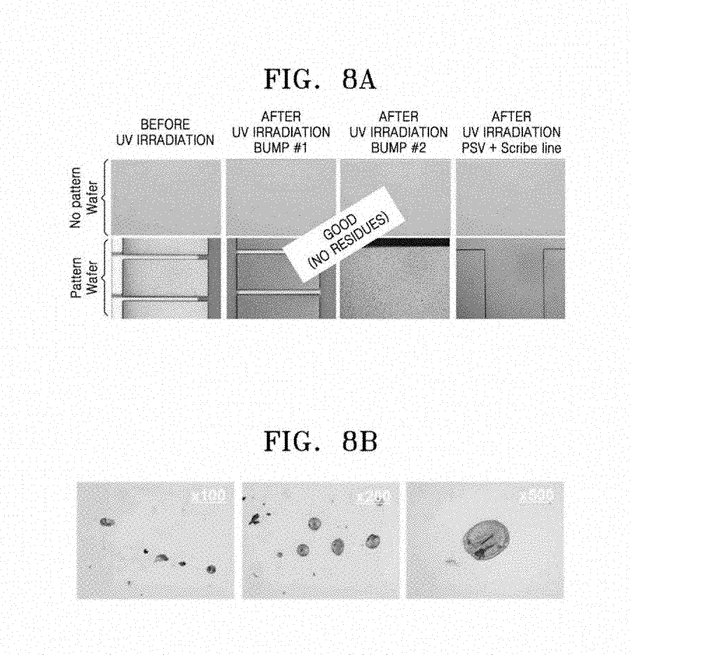

FIG. 8A includes microscope images showing whether residues remain after a UV tape layer is detached under various conditions when the UV tape layer is used as an anti-scratch protection layer in the method of manufacturing a semiconductor package, according to an embodiment of the present invention. The UV tape layer is attached onto a 200m wafer and then is detached under various conditions. After that, the surface of the wafer is observed. Heat is applied at 150° C. for 10 minutes before the UV tape layer is detached.

Referring to FIG. 8A, it is shown that no residues remain on the surface of the wafer or on a pattern of the wafer after the UV tape layer is detached regardless of whether a pattern is present on the surface of the wafer, regardless of whether UV light is irradiated, and regardless of the shape of the pattern on the surface of the wafer.

FIG. 8B includes microscope images showing whether residues remain after a foam tape layer is detached under various conditions when the foam tape layer is used as an anti-scratch protection layer in the method of manufacturing a semiconductor package, according to an embodiment of the present invention. The foam tape layer is attached onto a 200m wafer and then is detached under various conditions. After that, the surface of the wafer is observed. Heat is applied at 150° C. for 10 minutes before the foam tape layer is detached.

Referring to FIG. 8B, it is shown that residues remain on the surface of the wafer after the foam tape layer is detached.

According to the above results, since no residues are required after an insulating tape layer serving as an anti-scratch protection layer is detached, the UV tape layer is more preferable than the foam tape layer.

Operation S300 for forming the second plated pattern 30 on the bottom surface 12b of the insulating substrate 12 will now be described in detail.

Referring to FIGS. 31 to 3M, acid cleaning is performed and then the second UBM pattern 31 is formed on the bottom surface 12b of the insulating substrate 12. The second UBM pattern 31 may include a TiW layer, and a Cu layer on the TiW layer.

The Cu pattern 32, the Ni pattern 33, and the Au pattern 34 may be sequentially formed on the second UBM pattern 31 based on a plating process. For the plating process, a plating region may be defined by coating a photoresist layer and pattering the photoresist layer based on a lithography process. A descum process may be performed to obtain the photoresist pattern in an accurate shape. After the plating process is performed, the photoresist pattern is removed.

Operation S400 for forming the second passivation pattern 35 on the bottom surface 12b of the insulating substrate 12 having the conductive via pattern 14 will now be describe in detail.

Referring to FIG. 3N, the second UBM pattern 31 is etched into a certain pattern. The second plated pattern 30 may also be etched into the certain pattern. Subsequently, to form the second passivation pattern 35, a PBO layer may be coated as a second passivation layer. PBO is a material of the second passivation layer. The material of the second passivation layer may be replaced with PI, BCB, BT, phenolic resin, epoxy, silicone, SiO₂, Si₃N₄, or an equivalent thereof.

Subsequently, the second passivation layer is selectively exposed using a mask, and then a development process for selectively removing the second passivation layer is performed by supplying a developer. The second passivation pattern 35 obtained due to the development process is heated and cured. Additionally, a descum process may be performed on the second passivation pattern 35.

Referring to FIG. 3O, the second anti-scratch protection layer 18 formed on the first plated pattern 20 and the first passivation pattern 25 is removed.

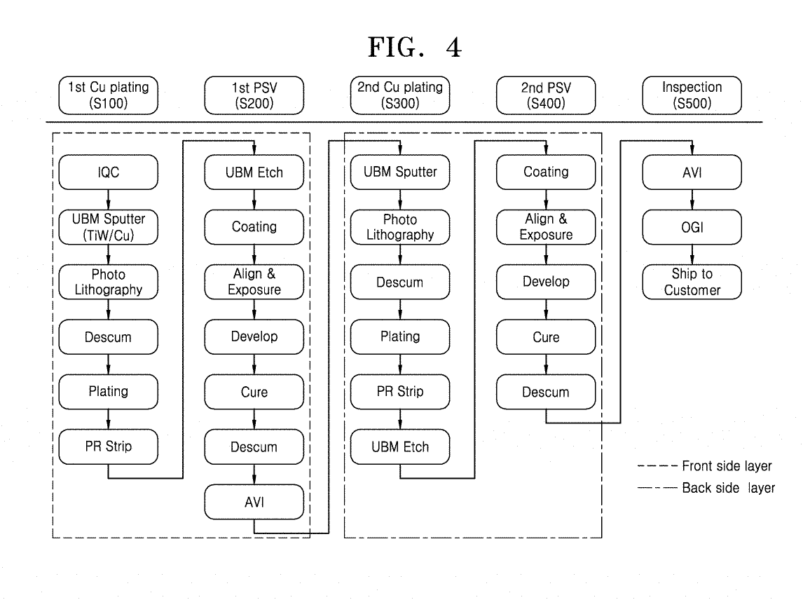

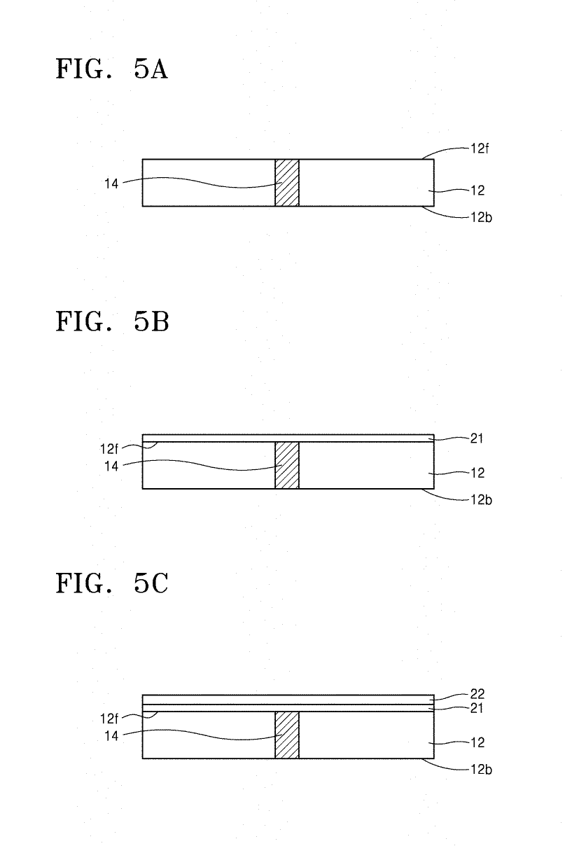

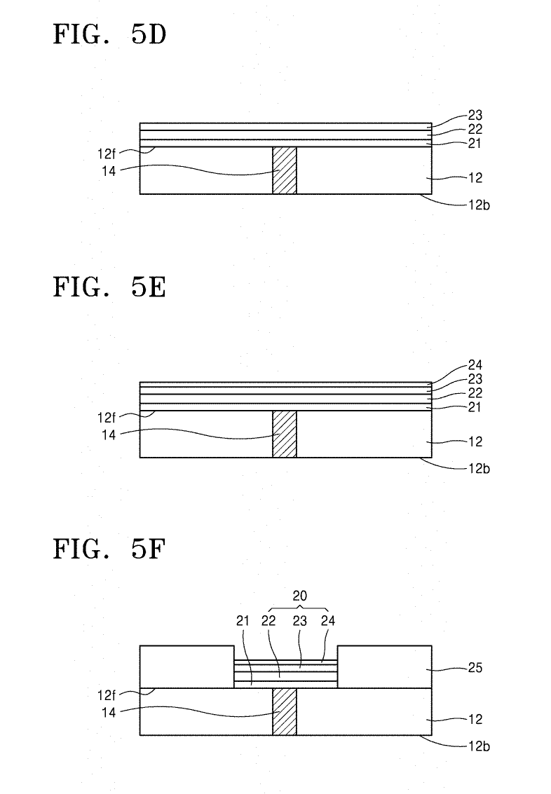

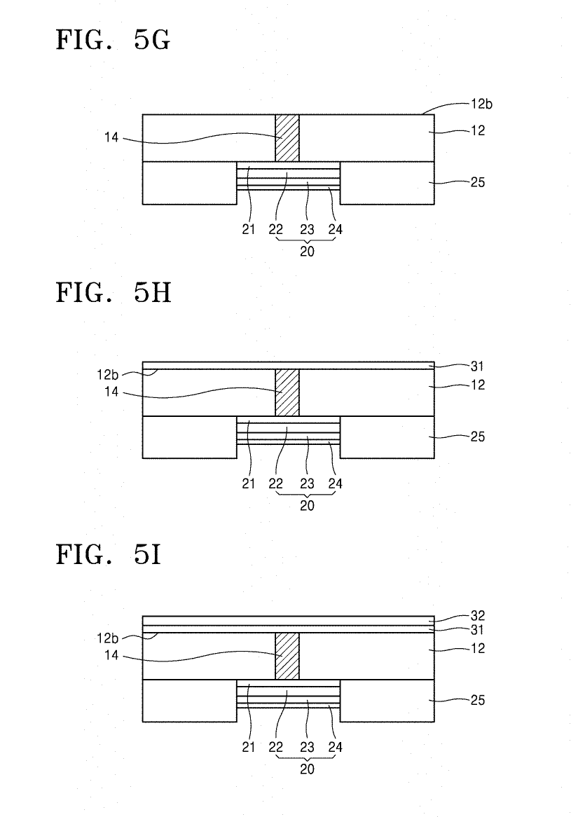

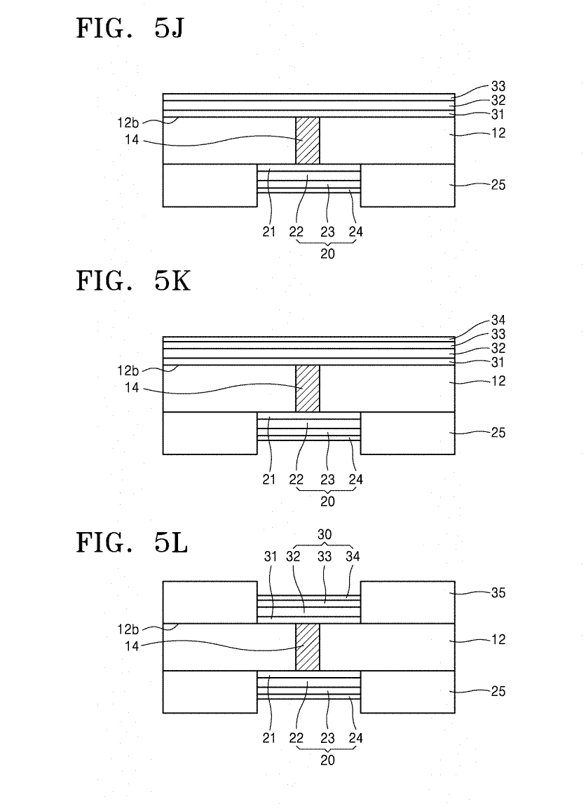

FIG. 4 is a flowchart of a method of manufacturing a semiconductor package, according to a comparative example of the present invention, and FIGS. 5A to 5L are sequential cross-sectional views for describing the method of manufacturing a semiconductor package, according to a comparative example of the present invention.

The method of manufacturing a semiconductor package, according to a comparative example of the present invention, is the same as the method of manufacturing a semiconductor package, according to an embodiment of the present invention, which is described above in relation to FIGS. 2 and 3, except that the first and second anti-scratch protection layers 16 and 18 are not formed and removed.

In the method of manufacturing a semiconductor package, according to a comparative example of the present invention, scratches may occur on the bottom surface 12b of the insulating substrate 12 while the first plated pattern 20 and the first passivation pattern 25 are being formed on the top surface 12f of the insulating substrate 12, and may also occur on the first plated pattern 20 and the first passivation pattern 25 formed on the top surface 12f of the insulating substrate 12 while the second plated pattern 30 and the second passivation pattern 35 are being formed on the bottom surface 12b of the insulating substrate 12.

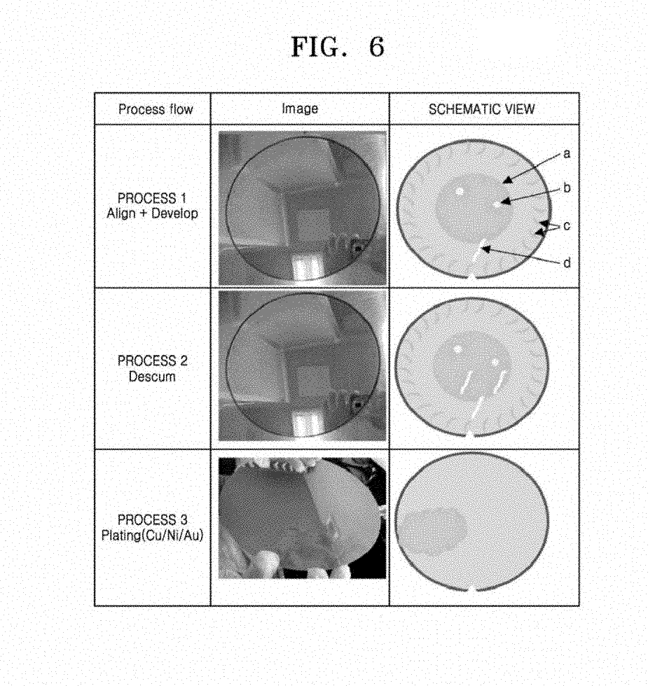

FIG. 6 is a table showing scratches occurring in the method of manufacturing a semiconductor package, according to a comparative example of the present invention.

Referring to FIG. 6, process 1 corresponds to a photolithography process including mask alignment and development. Scratches may occur on a substrate during process 1 for various reasons. For example, scratches (a) due to contact with a chuck for mounting the substrate thereon in equipment for the development process, scratches (b) due to a vacuum chuck of the development process, scratches (c) corresponding to flow marks of deionized (DI) water or a developer, and scratches (d) due to an exposure process may occur. Process 2 corresponds to a descum process. Scratches may occur on a bottom surface of the substrate during the descum process. Process 3 corresponds to a Cu/Ni/Au plating process. Overplating occurs on the bottom surface of the substrate during a process of plating Cu on a front surface of the substrate. However, the chuck marks and the flow marks are erased based on acid cleaning.

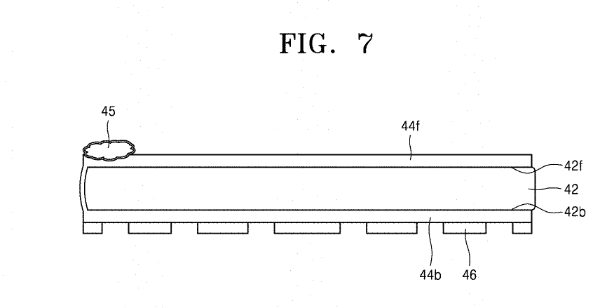

FIG. 7 is a cross-sectional view showing that overplating occurs in the method of manufacturing a semiconductor package, according to a comparative example of the present invention.

Referring to FIG. 7, when a plated layer 46 is formed on a front surface 42b of a substrate 42 having UBM patterns 44f and 44b thereon, overplating 45 occurs on a bottom surface 42f of the substrate 42. When an anti-scratch protection layer such as a deposited TiW layer is not provided and when a material (e.g., Cu/Au) having a low electrical resistivity (e.g., Cu: 16.78 nΩm and Au: 22.14 nΩm) and a high electron mobility is used to form a plated layer, electrons move through a plated layer at an edge between the front surface 42b and the bottom surface 42f of the substrate 42 and thus the overplating 45 occurs on the bottom surface 42f of the substrate 42.

On the contrary, according to an embodiment of the present invention (see FIGS. 3K to 3M), when a material (e.g., TiW/Ti) having a high electrical resistivity (e.g., Ti: 420 nΩm) and a low electron mobility is used to form an anti-scratch protection layer (e.g., the second anti-scratch protection layer 18), motion of electrons through a plated layer at an edge of a substrate may be suppressed and thus overplating may be prevented.

That is, according to an embodiment of the present invention, by employing an anti-scratch protection layer such as a deposited TiW layer, a deposited Ti layer, or an insulating tape layer, transition of plating to a bottom surface of a substrate in a plating process may be prevented and scratches on a front surface of the substrate may also be prevented. Furthermore, in addition to the anti-scratch protection function, the anti-scratch protection layer may facilitate handling of the substrate having a small thickness by preventing warpage of the substrate in a process of forming plated patterns or passivation patterns on both surfaces of the substrate.

As described above, according to an embodiment of the present invention, a method of manufacturing a semiconductor package by using both surfaces of a substrate, the method being capable of preventing scratches. However, the scope of the present invention is not limited to the above effect.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A method of manufacturing a semiconductor package, the method comprising:
providing an insulating substrate having a conductive via pattern;
forming a first anti-scratch protection layer on a bottom surface of the insulating substrate;
forming a first plated pattern and a first passivation pattern on a top surface of the insulating substrate;
removing the first anti-scratch protection layer;
forming a second anti-scratch protection layer on the top surface of the insulating substrate to cover the first plated pattern and the first passivation pattern;
forming a second plated pattern and a second passivation pattern on the bottom surface of the insulating substrate; and
removing the second anti-scratch protection layer.

2. The method of claim 1, wherein the insulating substrate comprises a glass substrate or a silicon substrate.

3. The method of claim 1, wherein the plated pattern comprises a single or stacked plated pattern including at least one selected from among copper (Cu), nickel (Ni), and gold (Au).

4. The method of claim 1, further comprising forming an under bump metal (UBM) pattern between the conductive via pattern and the plated pattern.

5. The method of claim 4, wherein the plated pattern comprises a single or stacked plated pattern including at least one selected from among Cu, Ni, and Au, and
wherein the UBM pattern comprises a titanium (Ti) layer, and a Cu layer on the Ti layer, or comprises a titanium tungsten (TiW) layer, and a Cu layer on the TiW layer.

6. The method of claim 1, wherein the anti-scratch protection layer comprises a deposited TiW layer or a deposited Ti layer.

7. The method of claim 1, wherein the anti-scratch protection layer is a detachable insulating tape layer and comprises an ultra-violet (UV) tape layer that is detachable by irradiating UV light thereon.

8. The method of claim 1, wherein the anti-scratch protection layer prevents warpage of the insulating substrate in a process of forming the plated pattern or the passivation pattern on the top and bottom surfaces of the insulating substrate.
